(19) United States
(12) Patent Application Publication
(10) Pub. No.: US 2008/0048194 A1
(43) Pub. Date: Feb. 28, 2008

(54) Nitride Semiconductor Light-Emitting Device

(76) Inventors: Hiromitsu Kudo, Amagasaki-shi (JP); Kazuyuki Tadatomo, Ube-shi (JP); Hiroaki Okagawa, Amagasaki-shi (JP); Tomoo Yamada, Amagasaki-shi (JP)

Correspondence Address: WENDEROTH, LIND & PONACK, L.L.P., 2033 K STREET N. W., SUITE 800, WASHINGTON, DC, 20006-1021, US

(21) Appl. No.: 11/629,532

(22) PCT Filed: Jun. 13, 2005
(86) PCT No.: PCT/JP05/11181

§ 371 Date: Jan. 23, 2007

(30) Foreign Application Priority Data
Jun. 14, 2004 (JP) 2004-175506

(51) Int. Cl. H01L 29/22

(52) U.S. Cl. 257/94; 257/E33.049

(57) ABSTRACT

A nitride semiconductor light emitting element having a laminate S made of a semiconductor crystal layer, wherein the laminate S includes an n-type layer 2, a light emitting layer 3 and a p-type layer 4. The p-type layer 4 has a p-type contact layer 42 to be in contact with the p-side electrode P2. The p-type contact layer 42 comprises a first contact layer 42a and a second contact layer 42b. The first contact layer 42a is in contact with the p-side electrode P2 on one surface and in contact with the second contact layer 42b on the other surface. The first contact layer 42a is made of Alₓ₁In_{y1}Ga_{z1}N (0<x1≦1, 0≦y1≦1, 0≦z1≦1), and the second contact layer 42b is made of Alₓ₂In_{y2}Ga_{z2}N (0≦x2≦1, 0≦y2≦1, 0≦z2≦1). 0≦x2<x1, 0≦y1≦y2, and the first contact layer 42a has a thickness of 0.5 nm-2 nm. By this constitution, the contact resistance between the p-type contact layer and the p-side electrode is reduced, and a nitride semiconductor light emitting element showing a lower operating voltage and reduced heat generation problem can be provided.

### TECHNICAL FIELD

The present invention relates to a nitride semiconductor light emitting element emitting the light of a short wavelength region from blue region to ultraviolet region, such as light emitting diode (hereinafter also referred to as LED), laser diode (hereinafter also referred to as LD) and the like. More specifically, the present invention relates to the constitution of a p-type contact layer in a nitride semiconductor light emitting element structure.

### BACKGROUND ART

In recent years, nitride semiconductors have been used as materials of LED or LD emitting the light of a short wavelength region from blue to ultraviolet region.

Nitride semiconductors are compound semiconductors represented by the formula: InₓAl_{y}Ga_{z}N wherein x+y+z=1, 0≦x≦1, 0≦y≦1, 0≦z≦1), which are exemplified by those having any composition such as GaN, InGaN, AlGaN, AlInGaN, AlN, InN and the like.

In the above-mentioned formula, at least a part of gallium (Ga), aluminum (Al) and indium (In), which are III group elements, may be substituted by boron (B), thallium (Tl) and the like, and at least a part of nitrogen (N) may be substituted by phosphorus (P), arsenic (As), antimony (Sb), bismuth (Bi) and the like. In the following description, the nitride semiconductor is also referred to as a GaN-based semiconductor.

FIG. 2 shows one embodiment of a general element structure of LED using a GaN-based semiconductor, wherein a laminate S1 comprising a GaN-based semiconductor crystal layer is formed on a crystal substrate 100 such as a sapphire substrate and the like via a low temperature growth buffer layer 100b made of a GaN-based semiconductor material. The laminate S1 has a pn junction structure consisting of an n-type layer and a p-type layer, wherein a light emitting layer 120 is formed at a junction part of the p-type layer and the n-type layer. Specifically, in the order from the lower side (crystal substrate side), an n-type clad layer 110 (which is, in this embodiment, also used as an n-type contact layer on which an n-side electrode is formed), a light emitting layer 120 (which may have a laminate structure such as multiple quantum well), a p-type clad layer 130 and a p-type contact layer 140 are laminated by vapor phase growth. P10 and P20 are respectively an n-side electrode and a p-side electrode, which are in ohmic contact with the n-type clad layer 110 and the p-type contact layer 140, respectively. In some cases, a pad electrode (not shown) for bonding may be further formed on the p-side electrode P20. In the light emitting element having a double hetero structure, the light emitting layer 120 is made of a crystal having a smaller band gap than that of the n-type clad layer 110 and the p-type clad layer 130. A light emitting element having a double hetero structure is said to show a light emitting output power not less than 10 times as high as that of a light emitting element having a homo junction (patent reference 1).

Patent references 1-9 cited for the explanation of the present invention and the background art are as follows.
patent reference 1: JP-A-8-330629
patent reference 2: JP-A-6-268259
patent reference 3: JP-A-9-312416
patent reference 4: JP-A-2000-323751
patent reference 5: JP-A-8-325094
patent reference 6: JP-A-10-135575
patent reference 7: JP-A-2000-331947
patent reference 8: JP-A-2002-164296
patent reference 9: JP-A-2002-280611

The n-type clad layer 110 is formed to have an n-type conductivity by doping with an n-type impurity. The p-type clad layer 130 and the p-type contact layer 140 are formed to have a p-type conductivity by doping with a p-type impurity and, where necessary, a treatment to afford low resistance such as electron beam irradiation, p-type annealing treatment and the like. The light emitting layer 120 can be formed to have an n-type conductivity or a p-type conductivity or to contain layers of these conductivities. In some cases, the light emitting layer 120 is an undoped layer which is intentionally free of doping with impurities (an undoped layer completely free of added impurities generally shows a weak n-type conductivity).

As a p-type impurity preferable for affording a p-type conductivity of a GaN-based semiconductor crystal layer, magnesium (Mg) is used (patent reference 2).

Even when the most preferable p-type impurity, Mg, is used, GaN-based semiconductors having p-type conductivity show low carrier concentration and low conductivity as compared to n-type GaN-based semiconductors. As a result, the series resistance in the p-type contact layer and the contact resistance between the p-type contact layer and a p-side electrode increase the operating voltage (e.g., forward voltage in LED, threshold voltage of oscillation in LD) of the GaN-based semiconductor light emitting element.

Therefore, various attempts have been made in the GaN-based semiconductor light emitting elements to decrease the operating voltage by designing the constitution of a p-type contact layer or the production method thereof. For example, in patent reference 2, magnesium (Mg) is used as a p-type dopant and gallium nitride (GaN), which is a binary mixed crystal free of In and Al, is used, so as to achieve good ohmic contact of the p-type contact layer with the p-side electrode.

In patent references 1 and 3, moreover, the p-type contact layer has a two-layer structure of high Mg concentration-doped layer/low concentration Mg-doped layer in the order from the electrode-forming layer. In patent reference 3, the thickness of the high Mg concentration-doped layer is preferably not less than 2 nm, and a thickness less than 2 nm is described to cause poor ohmic property and increased contact resistance.

Moreover, patent reference 4 discloses, as a method of preparing a low resistant p-type GaN-based semiconductor having a high hole concentration, which is a p-type carrier, by an organic metal compound vapor phase growth method (MOVPE method), a method comprising forming a second crystal layer represented by Al_{z}Gal_{1-z}N (0.7≦z≦1) on a first GaN-based semiconductor crystal doped with a p-type impurity and etching to remove the second crystal layer after completion of the growth.

Patent reference 5 discloses moreover that, since, during growth of a GaN-based semiconductor crystal doped with a p-type impurity by MOVPE method, the p-type carrier concentration in the obtained GaN-based semiconductor crystal increases as the hydrogen concentration of the gas used for blowing a material to the substrate decreases and the p-type semiconductor shows good properties, the hydrogen concentration in the gas of not more than 0.5% is preferable.

Moreover, patent reference 6 discloses that, since organic metal compounds such as trimethyl gallium (TMG), trimethylaluminum (TMA), bis(cyclopentadienyl)magnesium (Cp₂Mg) and the like used as the source materials for preparing a GaN-based semiconductor crystal by the MOVPE method is susceptible to decomposition by hydrogen, use of hydrogen as a carrier gas for feeding these compounds in a vapor phase state into a growth furnace by the MOVPE method results in an easy presence of Mg, which is a generating source of a p-type carrier, in the semiconductor layer.

However, demand for improved light emission efficiency (lower electrical power consumption) and lower operation voltage aiming at a longer life of elements and improved reliability with regard to GaN-based semiconductor light emitting elements never ceases, and further improvement has also been desired for a p-type contact layer.

### DISCLOSURE OF THE INVENTION

The present invention has been made in view of the above-mentioned situations, and aims to provide a GaN-based semiconductor light emitting element with a lower operation voltage, which is achieved by designing the constitution of a p-type contact layer.

In the GaN-based semiconductors, p-type dopants such as Mg and the like are difficult to activate, and only several % of the p-type dopant contributes to the generation of a p-type carrier. Therefore, the p-type layer needs to be doped with a larger amount of dopant than the n-type layer, which in turn degrades the crystal quality of the p-type layer than that of the n-type layer. Under the circumstances, when growing a GaN-based semiconductor crystal on a substrate to form a light emitting element structure, the uppermost layer to be grown last is a p-type layer, particularly a p-type contact layer. Accordingly, the surface of the p-type contact layer is exposed under high temperature conditions during cooling after completion of the crystal growth, or an annealing treatment to give a p-type layer and the like.

The present inventors have considered that nitrogen dissociation in the vicinity of the surface of the p-type contact layer at that time prevents reduction of operation voltage of the GaN-based semiconductor light emitting element, and improved the heat resistance of the p-type contact layer, which resulted in the completion of the present invention.

Accordingly, the present invention has the following characteristics.
(1) A nitride semiconductor light emitting element comprising a laminate comprising a nitride semiconductor crystal layer, wherein the laminate comprises an n-type layer and a p-type layer, and the p-type layer comprises a p-type contact layer to be in contact with a p-side electrode,

the p-type contact layer comprises the first contact layer to be in contact with the p-side electrode on one surface side and the second contact layer to be in contact with the other surface of the first contact layer,

the first contact layer consists of Alₓ₁In_{y1}Ga_{z1}N (0<x1≦1, 0≦y1≦1, 0≦z1≦1, x1+y1+z1=1),

the second contact layer consists of Alₓ₂In_{y2}Ga_{z2}N (0≦x2≦1, 0≦y2≦1, 0≦z2≦1, x2+y2+z2=1),

0≦x2<x1, and 0≦y1≦y2, and

the first contact layer has a thickness of 0.5 nm-2 nm.
(2) The element of the above-mentioned (1), wherein 0<x1≦0.2 and y1=0.
(3) The element of the above-mentioned (2), wherein x2=y2=0.
(4) The element of the above-mentioned (1), wherein the aforementioned p-type contact layer is doped with Mg, a p-type impurity, at a concentration of 1×10¹⁹-1×10²¹/cm³.
(5) The element of the above-mentioned (4), wherein the aforementioned p-type layer comprises a high Mg concentration layer having a layer thickness of 6 nm-30 nm, which includes the first contact layer and which is doped with Mg at a concentration of not less than 5×10¹⁹/cm³, and the other part has an Mg concentration of less than 5×10¹⁹/cm³.
(6) The element of the above-mentioned (5), wherein the aforementioned high Mg concentration layer has an Mg concentration of not more than 1×10²⁰/cm³.
(7) The element of the above-mentioned (5), comprising, between the aforementioned n-type layer and the aforementioned p-type layer, a light emitting layer including an InGaN crystal layer emitting a light of a wavelength of not more than 420 nm, wherein the p-side electrode is an opening electrode made of an opaque metal film.
(8) The element of the above-mentioned (7), wherein the aforementioned opening electrode has an area ratio of the metal film:opening of 40:60-20:80.
(9) The element of the above-mentioned (7), wherein the aforementioned p-side electrode has an insulating film formed thereon, which permits transmission of the light generated by the aforementioned light emitting layer, and the insulating film has a reflecting film on the surface thereof to reflect the light.

### BRIEF DESCRIPTION OF THE DRAWING

FIG. 1 is a schematic view showing an element structure of the GaN-based semiconductor light emitting element of the present invention. Hatching is applied to distinguish the regions.

FIG. 2 shows one embodiment of a general element structure of LED using the GaN-based semiconductor.

FIG. 3 is a schematic view showing another embodiment of the GaN-based semiconductor light emitting element of the present invention, which presents the element structure of the LED chip prepared in Experiment 3. FIG. 3(a) is a top view of the element, and presents a mesh pattern of the opening electrode. FIG. 3(b) shows a section along x-y in FIG. 3(a).

FIG. 4 is a partially enlarged view of the mesh opening electrode of FIG. 3(a).

FIG. 5 is a schematic view showing another embodiment of the GaN-based semiconductor light emitting element of the present invention, which presents the element structure of the LED chip prepared in Experiment 6. FIG. 5(a) is a top view of the element and FIG. 5(b) shows a section along x-y in FIG. 5(a).

### BEST MODE FOR EMBODYING THE INVENTION

In the present specification, the terms indicating the up and down relationship such as “lower layer side”, “lowermost part”, “immediately above” and the like are used to explain the position of each layer in the GaN-based semiconductor laminate structure contained in the GaN-based semiconductor light emitting element. These are expressions employed for convenience based on the lamination order, wherein a crystal substrate is the lower side, on which a GaN group semiconductor layer is formed in the laminate structure formation process, and they do not limit the absolute up and down directions of the element or a mounting direction (attitude on actual mounting) of the element. The term “immediately above” means an upper side in direct adjacency and the term “immediately below” means a lower side in direct adjacency.

The present invention is explained by referring to embodiments where the present invention is applied to LED.

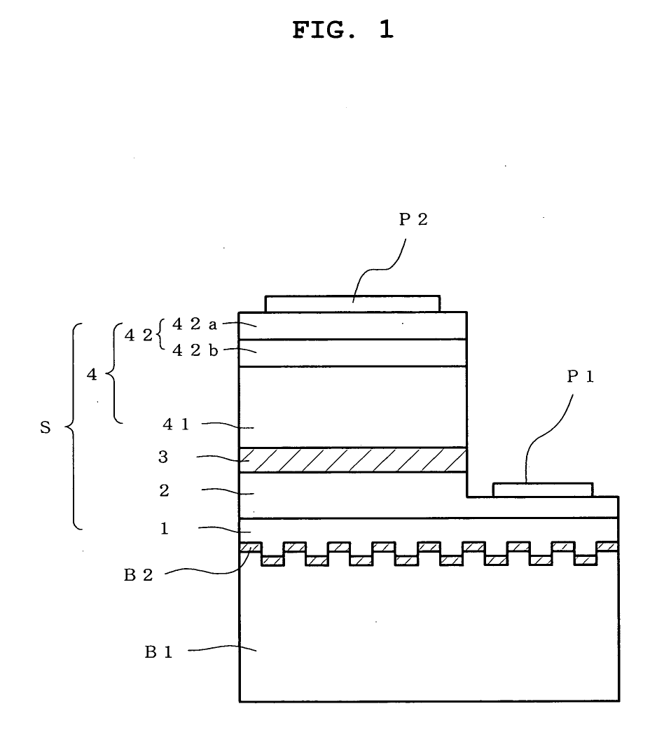

FIG. 1 is a schematic view showing one embodiment of the element structure of LED according to the present invention, wherein GaN-based semiconductor crystal layers are sequentially grown on a crystal substrate B1 to form a laminate S. The laminate S comprises an undoped layer 1, an n-type layer 2, a light emitting layer 3 and a p-type layer 4 in this order from the lower layer side. On the n-type layer 2 and p-type layer 4, an n-side electrode P1 and a p-side electrode P2 are formed, respectively. The n-side electrode P1 and p-side electrode P2 are electrodes to be in ohmic contact with the n-type layer 2 and p-type layer 4, respectively. In some cases, a pad electrode (not shown) for bonding is further formed on the p-side electrode P2. While the n-side electrode P1 can also function as a pad electrode, a pad electrode may be separately formed on the n-side electrode P1.

In some cases, the n-type layer 2 may independently include an n-type contact layer on which to form an n-side electrode, and an n-type clad layer which injects an n-type carrier into the light emitting layer 3. In the embodiment shown in this Figure, one layer acts as both layers.

The light emitting layer 3 aims at generating a light by recombination of carriers, and may be a single layer or a laminate structure, as mentioned below.

The p-type layer 4 includes a p-type clad layer 41 and a p-type contact layer 42. The p-type contact layer 42 has a double-layer structure comprising a first contact layer 42a on which to form a p-side electrode P2 and a second contact layer 42b immediately below. The p-type clad layer 41 injects a p-type carrier into the light emitting layer 3. The second contact layer 42b may also function as the p-type clad layer. Furthermore, other GaN-based semiconductor crystal layer may be placed between the light emitting layer 3 and the p-type clad layer 41, or between the p-type clad layer 41 and the second contact layer 42b.

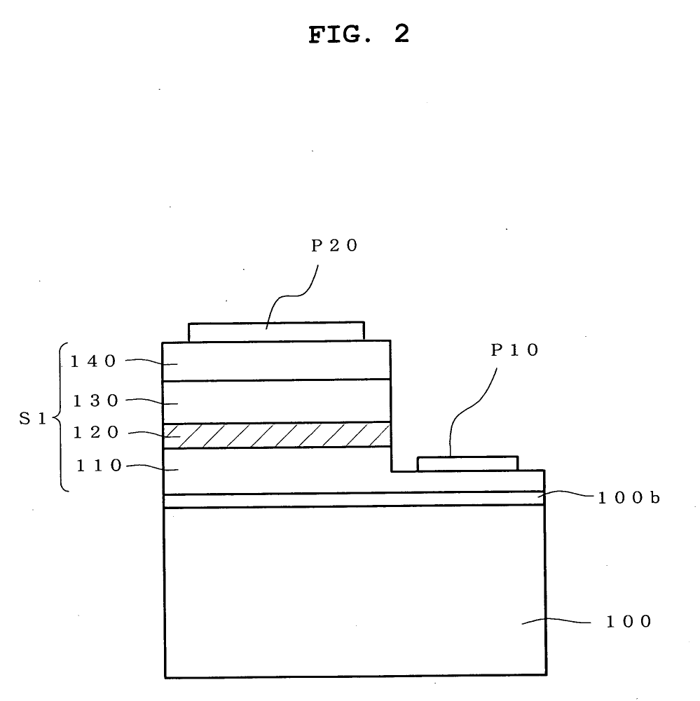

The upper surface of the crystal substrate may be flat as shown in FIG. 2. In the exemplary element structure of FIG. 1, the upper surface of a crystal substrate B1 is processed to have concaves and convexes (described below), a buffer layer B2 made of a GaN-based semiconductor material is formed on the concaves and convexes and an undoped GaN layer 1 and an n-type GaN clad layer 2 are grown covering the concaves and convexes. The laminate S is etched from the p-type layer side to partially expose the n-type GaN clad layer 2 and the n-side electrode P1 is formed on the exposed part. In addition, a p-side electrode P2 is formed on the upper surface of a p-type contact layer 42.

The light emitted from the light emitting layer 3 may be extracted from the upper side (from p-side electrode side) or the lower side (from the back side of the substrate) through the crystal substrate, and the form of the p-side electrode and the structure permitting normal disposition mounting or flip chip mounting can be determined, according to the respective case.

The crystal substrate may be any as long as it permits growth of a GaN-based semiconductor crystal. Preferable crystal substrate includes, for example, sapphire (C-plane, A-plane, R-plane), SiC (6H, 4H, 3C), GaN, AlN, Si, Spinel, ZnO, GaAs, NGO and the like. In addition, a substrate having such crystal as a surface layer can also be used. The plane orientation of the substrate is not particularly limited and it may be a just substrate, or a substrate having an off angle.

To improve the crystal quality of the GaN-based semiconductor crystal, a buffer layer is preferably interposed between the crystal substrate and the GaN-based semiconductor crystal layer. The material, formation method and formation conditions of buffer layer are those of known techniques. Preferable buffer layer materials include GaN-based semiconductor materials such as GaN, AlGaN, AlN, InN and the like. The growth temperature of the buffer layer is preferably lower than the growth temperature of the GaN-based semiconductor crystal layer to be formed immediately thereon, and is specifically 300° C.-700° C. The thickness of the buffer layer is preferably 10 nm-50 nm.

The dislocation density of the GaN-based semiconductor crystal can be decreased by processing to form concaves and convexes in dots, stripes and the like on the upper surface of the crystal substrate B1, and growing a GaN-based semiconductor crystal layer (patent reference 7, patent reference 8). Moreover, when a GaN-based semiconductor crystal is grown to bury the concaves and convexes and when a crystal substrate (e.g., sapphire substrate etc.) made of a material different from the GaN-based semiconductor material is used, a preferable effect (independent from reduction of dislocation density) in that the light-extraction efficiency of LED is increased can be afforded, since the interface between the crystal substrate and the GaN-based semiconductor crystal having different refractive indices scatters light (patent reference 9).

The GaN-based semiconductor crystal to be grown while burying the concaves and convexes is preferably GaN, particularly undoped GaN, since a high quality crystal with good flatness of the growth surface and low crystal dislocation density can be obtained easily. Using GaN, the crystal quality of an n-type layer 2, light emitting layer 3 and p-type layer 4, which grow thereon, can be improved.

For the method of processing to form concaves and convexes on the upper surface of the crystal substrate, arrangement pattern of the concaves and convexes, cross section of the concaves and convexes, growth process of GaN-based semiconductor crystal on the concaves and convexes and the like can be known from the above-mentioned patent references 7 to 9 and the like. The longitudinal direction of the concave grooves when they are formed in stripes as concaves and convexes, the width of the concave groove, the width of the convex ridge, amplitude of concaves and convexes (depth of concave groove) and the like can also be known from these publications and known techniques.

The light emitting layer may be a structure of a single composition crystal layer, or a multi-layer film structure made of plural layers having different band gaps, such as single quantum well (SQW) structure, multiple quantum well (MQW) structure and the like. In the light emitting layer of a quantum well structure, a well layer sandwiched by barrier layers is the site of light emission based on the recombination of carrier.

When a light emitting layer (well layer in the light emitting layer of quantum well structure) is made of InGaN, the light emitting wavelength can be widely controlled from about 360 nm (In content of 0) to the infrared wavelength region by adjusting the In ratio of the InGaN crystal. The light emitting wavelength can also be controlled by doping the light emitting layer with an n-type impurity and/or a p-type impurity.

LED wherein a well layer is formed with an InGaN crystal having a light emitting wavelength in the range of violet-near ultraviolet (wavelength 420 nm-360 nm) is preferable as an excitation light source of a semiconductor illumination apparatus using R (red), G (green) and B (blue) fluorescent materials and showing good color rendering properties.

By setting the crystal composition of an n-type clad layer to a composition with a band gap greater than that of the crystal composition of a light emitting layer, the carrier can be effectively confined in the light emitting layer. In the case of LED, since the electric current density during use is comparatively small, the band gap difference between the n-type clad layer and the light emitting layer does not need to be large. When the light emitting layer is a quantum well structure, the n-type clad layer may be free of band gap difference from the barrier layer (same composition), or with a smaller band gap than that of the barrier layer.

When an n-type GaN-based semiconductor is to be formed, silicon (Si), germanium (Ge), selenium (Se), tellurium (Te), carbon (C) and the like can be added as an n-type impurity.

The crystal composition of the p-type clad layer is preferably determined such that the band gap becomes greater than that of the light emitting layer. Specifically, to effectively confine the n-type carrier in a light emitting layer, the composition preferably affords a band gap difference from the light emitting layer (well layer in the case of quantum well structure) of at least not less than 0.3 eV.

When the light emitting wavelength is 400 nm, a preferable Al ratio x of the p-type clad is not less than 0.06. When the Al ratio x of AlₓGa₁₋ₓN exceeds 0.2, the crystal quality tends to be degraded and the activation degree of the p-type impurity (ratio of p-type impurity, from the added p-type impurities, contributing to the generation of p-type carrier) decreases markedly. Thus, x is preferably not more than 0.2, more preferably not more than 0.1.

When the crystal quality is degraded and the density of the threading dislocation defect becomes high, problems occur in that the diffusion of Mg and the like easily occurs along the defect, the crystal quality of the p-type contact layer to be formed thereon is degraded to lower the conductivity of the layer, the contact resistance with the p-side electrode increases and the like.

As the p-type impurity, for example, Mg, zinc (Zn), beryllium (Be), calcium (Ca), strontium (Sr), barium (Ba) and the like can be mentioned, with preference given to Mg since the activation degree of the p-type impurity can be increased.

When Mg is used as a p-type impurity, too low an Mg concentration of the p-type clad layer raises the series resistance of the p-type clad layer, whereas too high an Mg concentration markedly enhances light absorption by the p-type clad layer, thus impairing the light emitting efficiency. Thus, the Mg concentration of the p-type clad layer is preferably 5×10¹⁸/cm³-1×10²⁰/cm³, more preferably 1×10¹⁹/cm³-5×10¹⁹/cm³.

The thickness of the p-type clad layer is not particularly limited, and it can be determined in appropriate reference to known techniques. It is generally within the range of 10 nm-100 nm, preferably 20 nm-70 nm. When the p-type clad layer is formed from AlₓGa₁₋ₓN, the activation degree of Mg tends to decrease, which increase the series resistance of the p-type clad layer. Thus, when the Al ratio x is not less than 0.05, the thickness of the p-type clad layer is preferably not more than 50 nm.

In a p-type contact layer 4 having a double layer, the first contact layer 42a to be in contact with the p-side electrode P2 on one surface side is AlₓIn_{y1}Ga_{z1}N (0<x1≦1, 0≦y1≦1, 0≦z1≦1, x1+y1+z1=1). The second contact layer 42b to be in contact with the other surface of the first contact layer 42a is Alₓ₂In_{y2}Ga_{z2}N (0≦x2≦1, 0≦y2≦1, 0≦z2≦1, x2+y2+z2=1), where 0≦x2<x1 and 0≦y1≦y2 stand for the composition of each layer of the III group element, and the film thickness of the first contact layer 42a is 0.5 nm-2 nm.

The first contact layer 42a has a greater Al content than in the second contact layer 42b (0≦x2<x1), and its In content is the same as or smaller than that of the second contact layer 42b (0≦y1≦y2). This aims at increasing the content of Al showing strong binding force with N and at making the content of In showing weak binding force with N the same as or smaller, whereby the heat resistance of the first contact layer 42a becomes higher than that of the second contact layer 42b, and nitrogen dissociation from the vicinity of the surface of the contact layer, which is caused by exposure to a high temperature atmosphere during cooling after crystal growth, during p-type annealing treatment and the like, is reduced.

Furthermore, when the first contact layer has a composition wherein y1=0, i.e., free of In, the effect of reducing nitrogen dissociation can be enhanced further. The GaN-based semiconductor crystal with high crystal quality can be obtained more easily as the number of constituent elements decreases from quaternary crystal InAlGaN to ternary crystal AlGaN, and to binary crystal GaN. To improve the crystal quality, in the composition of the first contact layer, y1=0 is preferable. When x1 in the composition of Al exceeds 0.2, the crystal quality tends to be degraded, and the activation degree of p-type impurity markedly decreases. Thus, it is preferable 0<x1≦0.2.

The thickness of the first contact layer 42a is 0.5 nm-2 nm. When the thickness of the first contact layer 42a is less than 0.5 nm or exceeds 2 nm, the effect of reducing the forward voltage (Vf), operating voltage of LED, becomes small.

The second contact layer 42b shows an Al content lower than that of the first contact layer (0≦x2<x1), and the In content is the same as or greater than that of the first contact layer (0≦y1≦y2). This aims at setting a smaller band gap of the second contact layer than that of the first contact layer, whereby the activation degree of the p-type dopant in the second contact layer is relatively increased. As a result, the problems of decreased carrier concentration and decreased conductivity in the vicinity of the surface of the p-type contact layer, which are caused by the Al-containing composition first contact layer, are reduced.

Moreover, when the composition of the second contact layer is x2=x2=0, i.e., GaN, the difference in the optimal growth temperature from the first contact layer (containing Al) to be grown directly above preferably becomes small (the difference in the optimal growth temperature is great between GaN-based semiconductor crystal containing Al and GaN-based semiconductor crystal containing In). This effect is remarkable particularly when the first contact layer is AlGaN free of In. Since GaN is a binary crystal, good crystal quality can be easily achieved. Since the second contact layer is a base layer for growing the first contact layer and shows a great influence on the crystal quality of the first contact layer, the composition of the second contact layer is preferably GaN.

While the film thickness of the second contact layer 42b is not particularly limited, it is preferable to set the layer thickness of the whole p-type layers including the aforementioned p-type clad layer, the first contact layer and the like to not less than 100 nm in view of the balance with the n-type layer.

When the p-type layer is formed to have an appropriate thickness, deterioration of the light emitting layer during cooling after crystal growth, p-type annealing treatment, electrode annealing treatment and the like are suppressed due to the effect of a protection layer. Thus, the layer thickness of the second contact layer is preferably determined such that the layer thickness of the whole p-type layer is 100 nm-300 nm, more preferably 100 nm-200 nm.

When the layer thickness of the whole p-type layer is greater than 300 nm, the above-mentioned effect becomes saturated, and the problem of greater light absorption by Mg doping becomes noticeable. In addition, degraded production efficiency and wasting of materials, which are caused by a longer growth time, become problems. Moreover, thermal degradation of light emitting layer and undesirable diffusion of impurities, which are caused by a longer growth time of the p-type layer, also pose problems.

When the concentration of the p-type dopant in the p-type contact layer is set too low, series resistance and contact resistance with the p-side electrode become high due to the insufficient carrier concentration. When the p-type dopant concentration is set too high, series resistance also increases since the mobility of the carrier decreases due to degraded crystal quality. When the concentration of the p-type dopant is set too high, the surface of the p-type contact layer becomes less flat and the contact performance with the p-side electrode becomes poor.

When Mg is used as the p-type dopant, therefore, the first contact layer 42a and the second contact layer 42b preferably show an Mg concentration of 1×10¹⁹-1×10²¹/cm³.

Particularly, to reduce contact resistance with p-side electrode to a low level, Mg concentration of the first contact layer is preferably not less than 5×10¹⁹/cm³. In this case, not only setting the Mg concentration of the first contact layer to fall within in this concentration range, but also the Mg concentration is preferably set to not less than 5×10¹⁹/cm³ for the thickness of at least 6 nm, more preferably not less than 10 nm from the surface of the p-type contact layer (surface of the first contact layer) to the second contact layer. In this case, since the interface between the first contact layer and the second contact layer is a hetero interface (interface formed by crystal layers having different compositions), diffusion of Mg from the first contact layer to the second contact layer is suppressed, and the Mg concentration in the vicinity of the surface of the p-type contact layer is expected to be maintained high.

While Mg-doped p-type layer absorbs the light generated in the light emitting layer, the absorption amount increases as the amount of Mg contained in the whole p-layer increases. The wavelength of the light absorbed by the Mg-doped p-type layer becomes long since a higher Mg concentration deepens the impurity level formed by Mg, which increases the adverse influence on the output power (light emitting efficiency) of the light emitting element. Therefore, the part where Mg is added at a concentration of not less than 5×10¹⁹/cm³ is limited to the part within 30 nm, more preferably within 20 nm from the surface of the p-type contact layer (the surface of the first contact layer), and the Mg concentration for the part lower than that is set to less than 5×10¹⁹/cm³, whereby the influence on the light absorption due to Mg doping can be suppressed low.

To further suppress the light absorption due to Mg doping, it is preferable to reduce the Mg concentration to not more than 1×10²⁰/cm³, particularly preferably not more than 8×10¹⁹/cm³, also in the vicinity of the surface of the p-type contact layer where Mg is added at a high concentration.

For the p-side electrode P2 to be formed on the first contact layer 42a, electrodes conventionally known as ohmic electrodes for p-type GaN-based semiconductors can be appropriately used. Preferable p-side electrode includes, for example, an electrode obtained by laminating gold (Au) on a metal such as nickel (Ni), palladium (Pd), rhodium (Rh), platinum (Pt), titanium (Ti) and the like, and alloyed by a heat treatment. In addition, single materials or alloys of platinum group elements (Pd, Pt, iridium (Ir), osmium (Os), Rh, ruthenium (Ru)) can also be preferably used as electrode materials. Furthermore, semiconductor materials made of metal oxide such as indium-tin oxide (ITO), zinc oxide (ZnO) and the like can be used as materials of p-side electrode.

The p-side electrode can be a single layer film made of the above-mentioned materials, or a laminate film of a combination of some of the above-mentioned materials. When a laminate film is desired, a part that comes into contact with the first contact layer is formed with the above-mentioned materials, and a metal may be laminated thereon such as Au showing good bonding performance with bonding materials, Ag, Cu and Al superior in conductivity and thermal conductivity, and the like. In addition, to prevent unwanted chemical reaction and diffusion between materials of respective layers in a laminate film, a layer of a metal having a high melting point such as molybdenum (Mo), Pt, tungsten (W), Ir, Rh, Ru and the like may be interposed as necessary in the laminate film.

When the p-side electrode P2 is formed from a metal material and the light emitted from the light emitting layer 3 is extracted upwardly (p-side electrode side), an transparent electrode wherein an electrode film is formed thin to achieve transparency or an opening electrode having an opening for light extraction in the electrode film can be employed. When the light emitted from the light emitting layer 3 is taken out from the lower side (back side of substrate) through a crystal substrate, a metal p-side electrode P2 also acting as a reflecting film may be formed to cover the about whole surface of the upper surface of the first contact layer 42a.

When the p-side electrode is an transparent electrode made of a metal material, the film thickness is preferably not more than 20 nm to obtain sufficient transparency. Even if the film thickness is greater than this value, high transparency can be achieved by a heat treatment in the atmosphere containing oxygen. This is considered to be attributable to the formation of oxide due to the heat treatment.

Since p-type GaN-based semiconductor crystals have low conductivity, the diffusion of the electric current in the lateral direction (direction perpendicular to layer thickness direction) becomes insufficient inside the p-type layer. To compensate the diffusion of the electric current in the lateral direction in the p-side, a p-side electrode is formed to cover the about whole surface of the surface of the p-type contact layer.

When the Mg concentration of the p-type layer is reduced to suppress the light absorption by Mg doping, it is important that the p-side electrode should diffuse the electric current in the lateral direction since the conductivity of the p-type layer becomes low. This is particularly so in an embodiment where Mg is added at a concentration of not less than 5×10¹⁹/cm³ only in the part within 30 nm from the surface of the p-type contact layer (surface of the first contact layer) and Mg is added at a concentration lower than said concentration on the p-type layer on the lower side. Thus, the p-side electrode is desirably formed with a high conductivity, opaque metal film. The metal film preferable has a thickness of not less than 60 nm, more preferably not less than 100 nm.

To form the p-side electrode with an opaque metal film and extract the emitted light from the upper side of an element, the p-side electrode needs to be an opening electrode.

The opening electrode is particularly suitable for a light emitting element using InGaN emitting violet to near violet (about 420 nm-about 360 nm) light as a light emitting layer (well layer in light emitting layer with MQW structure). This is because the electric current fed from the opening electrode substantially flows only in the part beneath the metal film and does not spread easily beneath the opening, which then causes concentration of the electric current to certain part(s) of the light emitting layer (part(s) in the lower side from the electrode film part) in a light emitting element using an opening electrode, and the electric current density at said part becomes high.

In a light emitting element using InGaN having a light emitting wavelength longer than for blue (InGaN having comparatively high In ratio) as a light emitting layer, the degradation of the light emitting efficiency is striking when the density of the electric current flowing through the light emitting layer becomes high, as evidenced by the saturation of the light emission output power associated with increased drive current and change in the light emitting wavelength that occurs at a comparatively low electric current value. Therefore, use of an opening electrode causing concentration of the electric current to certain part(s) of the light emitting layer may decrease the light emitting efficiency.

In contrast, a light emitting element using InGaN having a light emitting wavelength shorter than for violet (InGaN having comparatively small In ratio) as a light emitting layer does not easily show saturation of light emission output power due to an increased electric current and change in the wavelength, and is suitable for operation at a high current density. When an opening electrode is used for such light emitting element, a preferable effect can be afforded in that the light emitting layer emits light with sufficiently high efficiency in the lower side of the electrode film part and the emitted light can be extracted to the outside through an opening free of an electrode film, without absorption by the electrode film.

As the shape of the opening electrode (shape formed by metal film), mesh, branched (comb is one kind of branched), meander and the like can be mentioned, where mesh is most preferable from the aspect of diffusion of electric current. The openings preferably have the same shape and size so that the intensity of light emission will be uniform in the light emitting surface of the element, and they are desirably arranged regularly.

The shape of the opening is not limited when the opening electrode is a mesh, and dot (triangle, quadrate, polygon, circle, ellipse etc. as the shape of dot), thin line (straight, curve) and the like can be mentioned. For good uniformity of the intensity of the emitted light in the light emitting surface of the element, moreover, the width of the opening (dot width, thin line width) and distance between adjacent openings are preferably decreased, and the range of 1 μm-50 μm is preferable.

A preferable ratio of the area of the metal film and that of the opening (both are projected areas on plane perpendicular to the thickness direction of substrate) in the opening electrode is 40:60-20:80, more preferably 30:70-20:80. When the area ratio of the metal film is smaller than the range, an influence of the contact resistance of the p-side electrode on the resistance of the whole element cannot be ignored.

The use of the opening electrode is not limited to an embodiment where the emitted light is extracted from the upper side of the element. When, for example, a p-side electrode is an opening electrode, an insulating film passing the light generated in the light emitting layer is formed on the p-side electrode, and a reflecting film is formed thereon, the emitted light can be extracted from the lower side of the crystal substrate with high efficiency, since the light that has passed the opening is reflected by the reflecting film.

The reflecting film in this embodiment can be formed using a material particularly superior in the reflection performance, such as Al, Ag and the like. In this embodiment, diffusion and reaction of materials between the reflecting film and the p-side electrode can be suppressed by an insulating film formed between the p-side electrode and the reflecting film. Consequently, an advantage is afforded in that the property of the p-side electrode is hardly deteriorated by exposure of an element to a high temperature during production steps of the element, during production steps of a product using the element, during use of the element and the like.

As the materials of the n-side electrode P1 to be joined with the n-type clad layer 2 (also serving as n-type contact layer), metals such as Al, vanadium (V), tin (Sn), Rh, titanium (Ti), chrome (Cr), niobium (Nb), thallium (Ta), Mo, W, hafnium (Hf) and the like, and alloy of two or more kinds of any such metals can be used.

The surface where the n-side electrode P1 is formed is exposed by a dry etching method such as reactive ion etching and the like, which partially removes p-type layer 4 and light emitting layer 3, after formation of p-type contact layer 42.

While LED in FIG. 1 has a crystal substrate B1, the crystal substrate used during growth of the GaN-based semiconductor crystal is not essential for the GaN-based semiconductor light emitting element of the present invention. That is, a GaN-based semiconductor crystal is laminated on a crystal substrate to give a laminate having a p-type contact layer as the uppermost layer, after which the crystal substrate may be removed. As a method for removing the crystal substrate, the following can be mentioned as examples: a method comprising abrasion of the substrate by polishing, a method comprising applying a physical stress on the interface between a crystal substrate and a GaN-based semiconductor crystal by mechanical vibration, heating-cooling cycle, insonation and the like to cause dissociation, a method comprising chemically dissolving a buffer layer formed in the interface between a crystal substrate and a GaN-based semiconductor crystal, a laser lift-off method comprising photochemically decomposing a buffer layer or a GaN-based semiconductor crystal in the interface between a crystal substrate and a GaN-based semiconductor crystal by a laser beam to cause dissociation, and the like. When a crystal substrate is removed, a base-member having a thickness easy to handle may be connected to the upper surface of a p-type contact layer so as to facilitate handling of a thin GaN-based semiconductor crystal layer laminate after removal of the crystal substrate. The base-member may be temporarily connected for handling, or constitute a part of the element. In the latter case, the base-member is preferably made of a conductive material so that the current can flow through the p-type contact layer via the base-member. In addition, a metal layer and the like may be used for mediation between the base-member and the p-type contact layer, so as to increase the connection strength or improve electric contact.

As a method for growing a GaN-based semiconductor crystal to be contained in the GaN-based semiconductor light emitting element of the present invention, conventionally known methods such as HVPE method, MOVPE method, MBE method and the like can be mentioned. Of these, MOVPE method is most preferable, since high quality crystal thin film can be formed at a practical growth rate.

For growth of a GaN-based semiconductor crystal by the MOVPE method, a substrate disposed on a susceptor set in a growth furnace is heated by a heating means such as a heater and the like, and an organometallic compound such as TMG, TMA, trimethylindium (TMI) and the like as a III-group source material and a thermally decomposable nitrogen-containing compound such as ammonia, hydrazine and the like as a V-group source material are fed. Mg to be added as an impurity is fed in the form of an organometallic compound such as Cp₂Mg and the like, and Si is fed in the form of a compound with hydrogen such as silane, disilane and the like. These source materials are fed into the reaction furnace in the form of a gas.

In the MOVPE method, source materials such as an organometallic compound, ammonia, silane and the like are fed into the growth furnace on dilution with a carrier gas. As the carrier gas, inactive gas such as nitrogen gas (N₂), rare gas and the like, hydrogen gas (H₂), or a mixed gas thereof are used. Particularly, hydrogen gas is generally used as a carrier gas for an organometallic compound source material. This is because thermal decomposition of organometallic compound is difficult in an atmosphere free of hydrogen gas, and crystal growth rate is markedly decreased.

During crystal growth by the MOVPE method, a substrate is heated to a high temperature of about 1000° C. or above. For the growth of a high quality crystal, it is important that the turbulence of gas flow due to the heat be prevented, and a gas containing the source materials be introduced into the growth furnace such that the gas forms a layer flow about parallel to the substrate surface. Hence, a sub-flow gas to control gas flow is fed into the growth furnace besides the source material and a carrier gas. As the sub-flow gas, an inactive gas, a hydrogen gas or a mixed gas thereof is conventionally used.

When a GaN-based semiconductor crystal wherein a p-type dopant such as Mg and the like is added is grown by the MOVPE method and a p-type dopant and hydrogen derived from a carrier gas or a V-group source material form a bond, the p-type dopant loses its activity and the crystal does not show p-type conductivity. This phenomenon is called hydrogen passivation. When a crystal with hydrogen passivation is heated to 400° C. or above in an atmosphere free of hydrogen, the bond between the p-type dopant and hydrogen is cleaved, and the dissociated hydrogen is released from the crystal to bring about p-type conductivity.

To prevent occurrence of hydrogen passivation, therefore, the concentration of the hydrogen component in the growth atmosphere is preferably set to a low level when a p-type impurity-added GaN-based semiconductor crystal is grown by the MOCVD method, and use of an inactive gas as a carrier gas and a sub-flow gas is preferable.

However, complete removal of hydrogen gas from the carrier gas and sub-flow gas causes difficult thermal decomposition of an organometallic compound and low crystal growth rate, as mentioned above. When the crystal growth rate is low, the growth to a given film thickness of the GaN-based semiconductor crystal layer requires a long time. As a result, the problem of possible thermal degradation as recited in the below-mentioned problems (i) to (iv) may occur. More preferably, therefore, an inactive gas is used as a sub-flow gas and a carrier gas for source materials other than the carrier gas for organometallic compound source materials, and a mixed gas of hydrogen gas and inactive gas is used as a carrier gas for the organometallic compound source material, so that the thermal decomposition of the organometallic compound can occur efficiently.

In this case, the ratio k of the hydrogen gas flow to the total flow of the carrier gas and the sub-flow gas to be fed into the growth furnace is preferably 0%≦k≦50%.

In the GaN-based semiconductor light emitting element of the present invention, a p-type contact layer has a double layer structure consisting of a first contact layer having a surface where a p-side electrode is formed, and a second contact layer in contact with the surface opposite from the surface of the first contact layer where a p-side electrode is formed. By defining the material compositions and the like of these layers as shown in the above-mentioned (1), the effects of reduced operating voltage, improved light emitting efficiency, elongated element life, improved reliability and the like can be afforded.

The present inventors consider that these effects are based on the following actions afforded by the constitution of the p-type contact layer unique to the present invention.

(a) Suppression of Nitrogen Dissociation on the Surface Where P-Side Electrode is Formed

By comparison of binding force between Al, Ga or In, which are III-group elements constituting a GaN-based semiconductor, and N, the binding force between Al and N is the strongest, and then in the order of Ga and N, and In and N. Thus, the heat resistance in the vicinity of the surface of the p-type contact layer can be increased higher than that of the inside by constituting the first contact layer exposed on the surface of the p-type contact layer with a GaN-based semiconductor crystal having a higher Al ratio and the same or lower In ratio as compared to those of the second contact layer located inside the p-type contact layer. By such constitution of the p-type contact layer, nitrogen dissociation in the vicinity of the surface, which occurs in a step where the surface of the p-type contact layer is exposed in a high temperature, such as during temperature decrease after completion of crystal growth (particularly when temperature is decreased while suppressing the ammonia flow), p-type annealing treatment and the like, can be suppressed, and an increase in the contact resistance with a p-side electrode to be formed on the surface can be suppressed.

(b) Inhibition of Reduced Conductivity of P-Type Contact Layer Due to Addition of Al

When a GaN-based semiconductor crystal contains Al, crystal band gap becomes high, and the activation degree of p-type impurity decreases. Thus, even if the concentration of p-type impurity is the same, the conductivity becomes problematically low. In contrast, in the p-type contact layer of the present invention, the first contact layer having a relatively higher Al content is a thin layer of not more than 2 nm, and the second contact layer formed immediately below is a GaN-based semiconductor crystal having a relatively small Al content and the same or higher In content, so that the band gap becomes smaller than that of the first contact layer. Consequently, the problem of reduced conductivity of p-type contact layer due to the reduced conductivity of the first contact layer can be decreased.

(c) Inhibition of Thermal Degradation Due to Shortened Growth Time

When a GaN-based semiconductor crystal contains Al, since binding force between Al-N is strong, the growth temperature may be set higher or the growth rate may be reduced as compared to those of a composition free of Al, thus allowing a growth over time to improve crystal quality. However, a higher growth temperature and a longer growth time of p-type contact layer are associated with the problems of thermal degradation as recited in the below-mentioned problems (i) to (iv).

Problem (i) The light emitting layer is degraded by heat. While InGaN is preferably used as a material of a light emitting layer, since InGaN has a comparatively low decomposition temperature, decomposition occurs on exposure to a high temperature for a long time. There is also a problem of diffusion of In, released by decomposition, to other layers.

Problem (ii) Nitrogen dissociation may occur in a layer having a relatively low Al content on the lower side, and inhibition of p-type conductivity appearance and the problem of decreased crystal quality may be developed.

Problem (iii) Undesired diffusion of impurity occurs. It includes diffusion of the dopant in the clad layer into a light emitting layer and diffusion from the light emitting layer into the clad layer when doping the light emitting layer. Once such diffusion occurs, light emitting efficiency of light emitting layer decreases. Particularly, Mg preferable as a p-type impurity is easily diffused, and Mg diffused into the light emitting layer problematically acts as a nonradiative center. While such diffusion easily occurs along the threading dislocation of the crystal, the density of the threading dislocation is difficult to reduce in a GaN-based semiconductor crystal.

problem (iv) In a different example of undesired diffusion of impurity, p-type dopant added at high concentration in the vicinity of the surface of the p-type contact layer to decrease the contact resistance with the p-side electrode diffuses into a layer having a lower dopant concentration, and the contact resistance becomes high.

In contrast, in the present invention, the thickness of the first contact layer having a relatively high Al content is not more than 2 nm, and the necessary growth time is shortened. Thus, the above-mentioned problem of thermal degradation is reduced.

The effect of the above-mentioned (c) becomes remarkable particularly when the MOVPE method is used for crystal growth. This is because the growth rate of a GaN-based semiconductor crystal containing Al needs to be lower than that of a layer free of Al, since the Al source material, TMA, easily reacts in a gaseous phase before reaching the substrate surface to often cause growth irregularity and the like. For superior growth of a crystal film while suppressing such reaction, the feeding rate of TMA (mol number of TMA to be fed into growth furnace per unit time) should be decreased. When AlGaN is grown, the feeding rates of TMA and TMG are determined to achieve a given composition ratio of Al and Ga in the crystal. The feeding rate of TMG needs to be determined according to the upper limit of the feeding rate of TMA, at which a good crystal film can be obtained. Thus, the feeding rate of TMG needs to be also decreased and, as a result, the growth rate becomes lower, and the time necessary for growing a crystal film of a given thickness becomes longer. In contrast, in the present invention, the thickness of the first contact layer containing Al is not more than 2 nm, and the growth time can be shortened. Thus, the above-mentioned problem of thermal degradation can be reduced.

The above-mentioned effect (c) is also effective for growing a p-type GaN-based semiconductor crystal using the MOVPE method and by reducing the hydrogen concentration in the growth furnace. A low hydrogen concentration during growth by the MOVPE method is preferable since it increases the p-type carrier concentration and affords favorable properties as a p-type semiconductor, as disclosed in patent reference 5. On the other hand, decomposition of an organometallic compound, which is a source material, becomes difficult, which in turn decreases the growth rate of a GaN-based semiconductor crystal. To deal with it, in the present invention, the thickness of the first contact layer is as thin as not more than 2 nm, and the growth time is shortened even for growth at a low hydrogen concentration. Thus, the above-mentioned problem of thermal degradation can be reduced.

### EXAMPLES

Experiments were conducted wherein the thicknesses of the first contact layer and the second contact layer were variously changed and respective properties were determined.

Experiment 1

(Preparation of Processed Sapphire Substrate)

On the surface of a C-plane sapphire substrate having a diameter of 2 inches was formed plural stripe patterns made of a photoresist film. The direction of the stripe was parallel to the <1-100> direction of sapphire and the width of the stripe and the distance between stripes were respectively 3 μm. Next, grooves with 1 μm depth were formed in the exposed surface of the sapphire substrate by reactive ion etching. Then, the photoresist film was removed to give a processed sapphire substrate having plural parallel stripe concaves and convexes on the surface.

(Growth of Buffer Layer)

The processed sapphire substrate prepared above was set in an MOVPE apparatus growth furnace of a normal pressure, horizontal type, heated to 1100° C. under a hydrogen gas atmosphere to perform thermal etching of the surface. Then, the temperature was lowered to 330° C. and TMG and TMA as III-group source materials and ammonia as a V-group source material were flown to grow an AlGaN buffer layer having a thickness of 20 nm.

(Growth of N-type Clad Layer)

Then, the temperature was raised to 1000° C., TMG and ammonia were supplied as source materials to grow an undoped GaN crystal layer (2 μm thick at a convex part on the substrate surface) while burying the concaves and convexes on the surface of the processed sapphire substrate. Silane was flown to grow an Si doped n-type GaN clad layer in a thickness of 3 μm.

(Growth of Light emitting Layer)

Then, the temperature was lowered to 800° C., and a light emitting layer having an MQW structure comprising a laminate of 6 periods of a pair of GaN barrier layer (thickness 10 nm) and InGaN well layer (light-emitting wavelength 380 nm, thickness 3 nm) was formed. During the growth of the InGaN well layer, TMG and TMI were flown as III-group source materials and the feed amounts of TMG and TMI were adjusted so that the light-emitting wavelength of the InGaN well layer would be 380 nm.

(Growth of P-Type Clad Layer)

Subsequently, the growth temperature was raised to 1000° C., TMG and TMA were used as III-group source materials and Cp₂Mg was used as a p-type impurity source material to form a p-type Al_{0.1}Ga_{0.9}N clad layer having a thickness of 50 nm. The feed amount of Cp₂Mg was adjusted so that the Mg concentration of the p-type Al_{0.1}Ga_{0.9}N clad layer would be 2×10¹⁹/cm³.

(Growth of P-Type Contact Layer)

Then, a p-type contact layer consisting of double layers of the first contact layer and the second contact layer was grown. After growing the p-type clad layer, feeding of TMA was stopped and TMG, ammonia and Cp₂Mg were fed to grow the second contact layer made of GaN. Then, TMA was fed again to grow the first contact layer made of Al_{0.03}Ga_{0.97}N. The feed amount of Cp₂Mg was adjusted so that the Mg concentration of the first contact layer and the second contact layer would be 8×10¹⁹/cm³.

During the growth of the second contact layer, hydrogen gas was used as a carrier gas for TMG and ammonia, and nitrogen gas was used as a sub-flow gas.

During the growth of the first contact layer, a mixed gas of hydrogen gas and nitrogen gas was used as a carrier gas for TMG and TMA, and nitrogen gas was used as a sub-flow gas and a carrier gas for ammonia. The ratio (flow ratio) of hydrogen gas in the carrier gas of TMG and TMA was suppressed to not more than 30% by controlling the flow amount of hydrogen gas and nitrogen gas using a mass flow controller. As a result, the flow ratio of hydrogen gas was about 8% of the total flow of the sub-flow gas and carrier gas introduced into the growth furnace. The growth rate of the first contact layer at this time was about 1/10 of the rate when Al_{0.03}Ga_{0.97}N was grown under the same conditions except that hydrogen gas was used as a carrier gas of TMG and TMA (which achieved a flow ratio of hydrogen gas of about 53% in the total flow of the sub-flow gas and carrier gas introduced into the growth furnace).

Samples 1-6 were prepared wherein the total thickness of the first contact layer and the second contact layer was fixed to 100 nm, and the thickness of the first contact layer and the second contact layer was changed as shown in the following Table 1, processed into chips as mentioned below, and the properties thereof were examined.

In the sample of sample No. 1, the second contact layer made of GaN was grown to be 100 nm thick, and the first contact layer was not grown.

(Temperature Decrease) At the time point when the first contact layer grew to a predetermined thickness, the feeding of TMG and TMA was stopped and the heater was turned off to allow temperature decrease by natural cooling. Simultaneously with the cease of TMG and TMA feeding, the flow amount of ammonia was reduced to about 1/250 of that during crystal growth. In this way, the temperature was lowered to 800° C. while introducing nitrogen gas and a slight amount of ammonia into the growth furnace. When the temperature reached 800° C., the feeding of ammonia was completely stopped, and the temperature was lowered to room temperature while flowing only nitrogen gas.

In this way, a wafer comprising a processed sapphire substrate and a near violet LED structure formed thereon, which is made of a laminate of nitride semiconductor crystal and has a light-emitting wavelength of 380 nm, was obtained.

(Formation of P-Side Electrode)

On the p-type contact layer of the above-mentioned wafer was formed a translucent laminate of Ni layer and Au layer as a p-side electrode by an electron beam vapor deposition method, with the Ni layer on the contact side with the p-type contact layer. Thereafter, to promote the ohmic contact with the p-type contact layer, a heat treatment was applied at 400° C. for 1 min. The p-side electrode was formed in a predetermined shape by previously forming, on the upper surface of the p-type contact layer, a photoresist film patterned to have openings having a predetermined p-side electrode shape, forming a p-side electrode thereon, and lifting off the photoresist film. Moreover, a pad electrode having a 400 nm thick Au film was formed on the surface of the p-side electrode for bonding of a current-carrying wire to the p-side electrode.

(Formation of N-Side Electrode)

The p-type contact layer, p-type clad layer and the light emitting layer were partially removed from the surface side (on which nitride semiconductor crystal laminate was formed) of the wafer by reactive ion etching to form a concave exposing the n-type GaN contact layer. On the surface of the exposed n-type GaN contact layer were laminated Al (50 nm thick), Ti (30 nm thick) and Au (400 nm thick) in this order by an electron beam vapor deposition apparatus. Then, a heat treatment was applied at 400° C. for 1 min (simultaneously with the treatment of the above-mentioned p-side electrode) to promote ohmic contact with the n-type contact layer. The n-side electrode was also formed in a given shape by a method using a photoresist film, like the p-side electrode.

(Chip Formation)

After formation of the p-side electrode and n-side electrode, the sapphire substrate was ground to 90 μm thick, which was followed by scribing and element separation by breaking to give an LED chip. The shape of the upper surface of the LED chip was square and the length of one side thereof was about 350 μm.

(Evaluation)

The LED chips prepared by the above-mentioned method were die bonded on a stem, and a current-carrying wire was bonded to each electrode. By the measurement of the properties of the LED chips at current of 20 mA, the central wavelength of emitted light was about 380 nm and the output power measured using an integrating sphere was about 7 mW. These values were almost the same irrespective of the constitution of the p-type contact layer. On the other hand, the forward voltage (Vf) showed different values depending on the constitution of the p-type contact layer, as shown in the following Table 1.

TABLE 1

| | film thickness | film thickness | |
|---|---|---|---|
| Sample | (nm) of the first | (nm) of the second | |
| number | contact layer | contact layer | Vf(V) |
| 1 | 0 | 100 | 3.5 |
| 2 | 0.5 | 99.5 | 3.4 |
| 3 | 1 | 99 | 3.3 |
| 4 | 2 | 98 | 3.5 |
| 5 | 5 | 95 | 3.9 |
| 6 | 10 | 90 | 4.1 |

As shown in Table 1, with the double layer structure of the p-type contact layer consisting of the first contact layer and the second contact layer, and the film thickness of the first contact layer of not more than 2 nm, Vf of LED could be equivalent to or lower than that of a p-type contact layer having a single layer structure.

Experiment 2

In the same manner as in Experiment 1 except that the film thickness of the first contact layer was fixed to 1 nm and the second contact layer was divided into two layers having different Mg concentrations, an LED chip was prepared and evaluated.

To be specific, the second contact layer was divided into two layers of an high Mg concentration layer having an Mg concentration of 5×10¹⁹/cm³ on the side in contact with the first contact layer, and an low Mg concentration layer having an Mg concentration of 1×10¹⁹/cm³ on the side in contact with the p-type Al_{0.1}Ga_{0.9}N clad layer. The combined film thickness of the high Mg concentration layer and the low Mg concentration layer was fixed to 99 nm, and LED chips having various thicknesses of the high Mg concentration layer of 0 nm, 5 nm, 10 nm, 20 nm, 30 nm and 99 nm were prepared.

As a result, Vf was 3.3-3.5V for the samples having a film thickness of the high Mg concentration layer of not less than 5 nm, whereas it was 3.9V for the samples having a film thickness of the high Mg concentration layer of 0 nm, i.e., samples having an Mg concentration of the whole second contact layer of 1×10¹⁹/cm³. As regards the result, it is assumed that, in the samples having a film thickness of the high Mg concentration layer of 0 nm, the amount of Mg diffused from the first contact layer to the second contact layer increased and the Mg concentration in the vicinity of the surface of the p-type contact layer decreased. Therefrom it is suggested that a part where Mg is added at a high concentration should be formed to have a thickness of at least not less than 6 nm from the surface of the p-type contact layer.

In contrast, the output power of the samples having a film thickness of the high Mg concentration layer of 30 nm and 99 nm was almost the same as that in Experiment 1, but it was 5-15% higher than each sample of Experiment 1 for the samples having a film thickness of the high Mg concentration layer of not more than 20 nm. In this case, the samples having a smaller film thickness of the high Mg concentration layer showed higher output powers. Therefrom it is suggested that a part where Mg is added at a high concentration should be formed to have a thickness of not more than 30 nm from the surface of the p-type contact layer.

The light emitting pattern of the luminescent surface (surface on the p-side electrode side) of the samples prepared in Experiment 2 was examined. As a result, the samples having a film thickness of the high Mg concentration layer of not more than 30 nm showed intense luminescence in the vicinity of the p-side pad electrode and the area between the p-side pad electrode and the n-side electrode, as compared to other parts. The strong tendency was seen particularly when the electric current flowing through the LED chip was small.

Experiment 3

In the same manner as in the sample having a film thickness of the high Mg concentration layer of 20 nm in Experiment 2 except that an opening electrode comprising an opening and a metal film with an Au layer (film thickness 100 nm) laminated on a Ni layer (film thickness 30 nm) was employed for p-side electrode instead of a translucent electrode, an LED chip was prepared and evaluated.

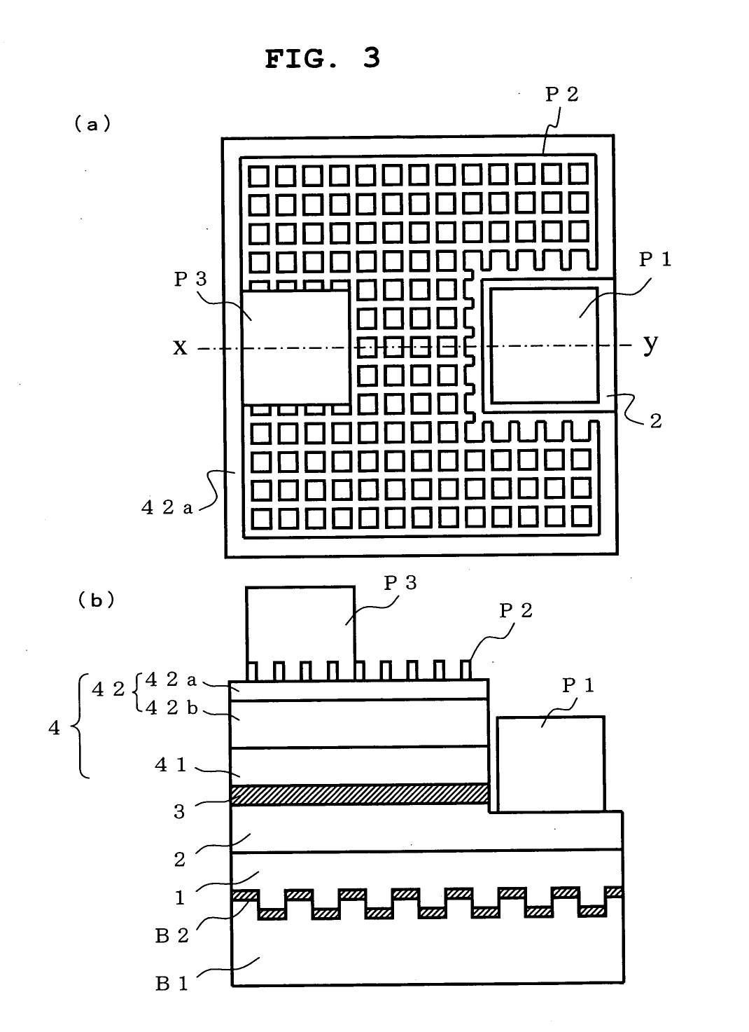

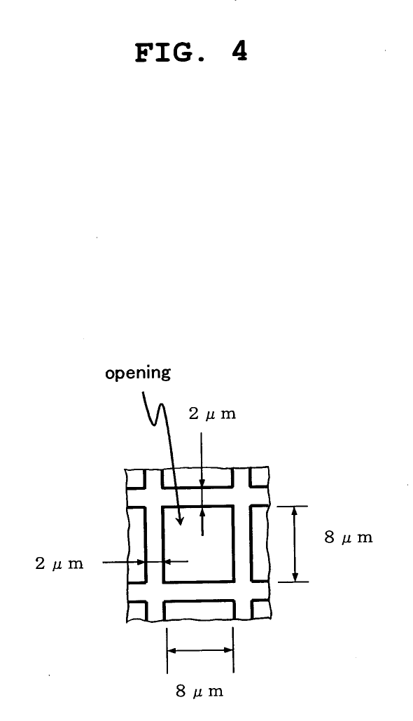

As shown in FIG. 3, the opening electrode was a mesh with square openings regularly disposed vertically and horizontally. In FIGS. 3(a) and 3(b), P1 is a pad electrode on the n side, P2 is a mesh opening electrode on the p side and P3 is a pad electrode on the p side. As shown in the partially enlarged view of FIG. 4, the detailed size of the mesh pattern of the mesh opening electrode P2 was: length of one side of opening, about 8 μm and width of stripe metal film separating the adjacent openings, about 2 μm. Hence, in this opening electrode, [area of metal film]:[area of opening]=36:64.

By the comparison of Vf and output power of the LED chip with those of the sample having a film thickness of the high Mg concentration layer of 20 nm in Experiment 2, Vf was about the same and the output power was higher by about 5%. In addition, the light emitting pattern of the light emitting surface was examined. As a result, the pattern was almost uniform over the entire surface and the light emitting pattern did not change when the electric current flown through the LED chip was changed.

Experiment 4

In the same manner as in Experiment 3 except that the length of one side of the opening of a mesh opening electrode was about 10 μm ([area of metal film]:[area of opening]=31:69), an LED chip was prepared and evaluated.

By the comparison of Vf and output power of the LED chip with those of the sample of Experiment 3, Vf was about the same and the output power was higher by about 3%. In addition, the light emitting pattern of the light emitting surface was examined. As a result, the pattern was almost uniform over the entire surface and the light emitting pattern did not change when the electric current flown through the LED chip was changed.

Experiment 5

An experiment was conducted wherein LED chips comprising InGaNs having light-emitting wavelengths of 400 nm, 420 nm and 440 nm as the light emitting layers were compared for the output power between the use of a translucent electrode as the p-side electrode and an opening electrode as the p-side electrode.

LED chips having a translucent electrode as a p-side electrode were prepared in the same manner as the sample having a film thickness of the high Mg concentration layer of 20 nm in Experiment 2, except that the feeding amount of the source material for growing the InGaN well layer was controlled such that the light-emitting wavelength was 400 nm, 420 nm or 440 nm and evaluated. LED chips having an opening electrode as a p-side electrode were prepared in the same manner as in the sample of Experiment 3, except that the feeding amount of the source material for growing the InGaN well layer was controlled such that the light-emitting wavelength was 400 nm, 420 nm or 440 nm and evaluated.

By the comparison of the output powers of the samples having the same light-emitting wavelength but different p-type electrodes, the output of the sample using the opening electrode was greater than that of the sample using the translucent electrode, when the wavelengths were 400 nm and 420 nm. On the other hand, when the light-emitting wavelength was 440 nm, the output power of the sample using the opening electrode was equal to or a little lower than that of the sample using the translucent electrode.

Experiment 6

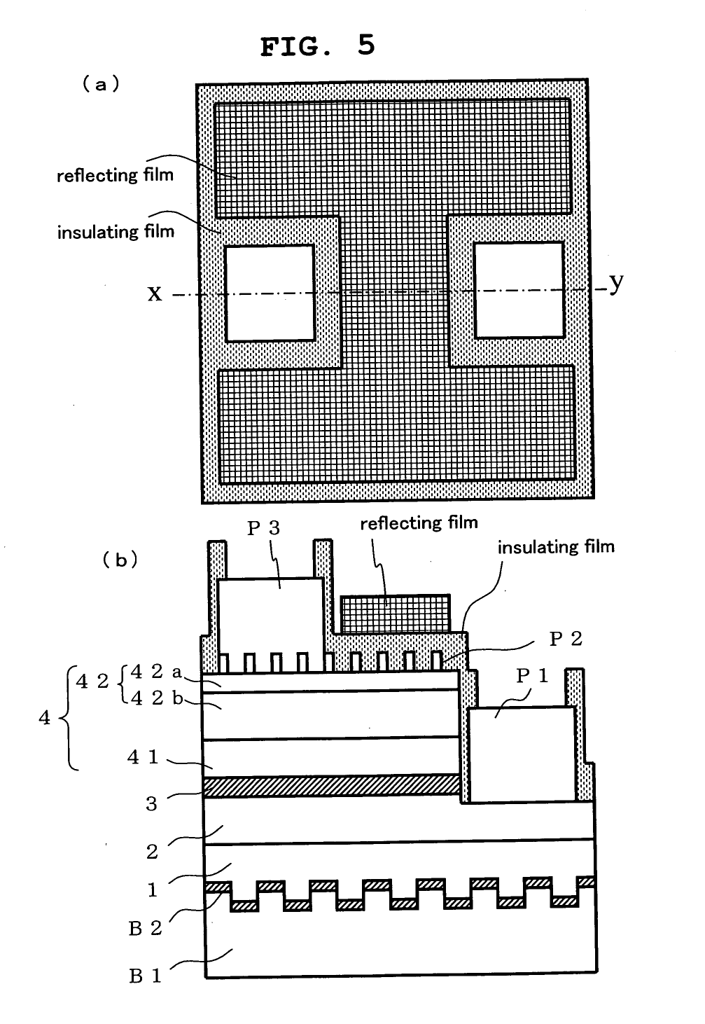

As shown in FIG. 5, an insulating film made of SiO₂ was formed on a p-side electrode, which was an opening electrode having the same constitution as in Experiment 3, and a reflecting film made of Al was formed thereon to give a light emitting element. In FIGS. 5(a) and 5(b), P1 is a pad electrode on the n side, P2 is a mesh opening electrode on the p side and P3 is a pad electrode on the p side. This element was prepared in the same manner as in the sample of Experiment 3 up to the formation of the n-side electrode (including heat treatment), except that a Ti layer (film thickness 10 nm) was laminated on the surface of an Au layer during formation of the opening electrode. After formation of the n-side electrode, an SiO₂ film (film thickness 300 nm) was formed by plasma CVD, and an Al layer (film thickness 200 nm) was further formed on its surface by an electron beam vapor deposition method. A part of the SiO₂ film was removed by dry etching to respectively expose a part of the surface of the pad electrode on the p side and a part of the surface of the n-side electrode.

The LED chip was flip-chip bonded onto the stem by Au-Sn soldering and Vf and the output power were measured at an electric current of 20 mA.

As a result, Vf was about the same as in the sample of Experiment 3, and the output power measured using an integrating sphere showed an increase of about 30% as compared to the sample of Experiment 3.

The crystal composition, film thickness and Mg concentration of the GaN-based semiconductor crystal layer shown in each of the above-mentioned Experiments are designed values, and the measured values of the actually obtained products are subject to production errors and the like.

In each of the above-mentioned Experiments, the films made of GaN-based semiconductor materials were grown by the MOVPE method. Using this method, for example, a film having a predetermined thickness can be grown by the following steps.

(A) Using predetermined growth conditions, a film is grown, which has a thickness measurable by an observation means such as transmission electron microscopic (TEM), scanning electron microscope (SEM) and the like or an interference type film thickness meter and the like, and the film-forming rate (film thickness grown in unit time) under said growth conditions is determined from the relationship with the time required for the growth.

(B) From the film-forming rate obtained in (A), the time required for growing a film having a desired thickness under said growth conditions is determined.

(C) Under said growth conditions, the film is grown for the required time obtained in (B).

The film thickness of AlGaN layer and GaN layer prepared in each Experiment was confirmed to have become a generally designed value, by measuring the depth direction distribution of Ga and Al by SIMS (Secondary Ion Mass Spectroscopy). Particularly, when the film thickness was small, XPS (X-ray Photoelectron Spectroscopy), which is an analysis method having higher resolution in the thickness direction, was also used for confirmation.

Moreover, the Mg doped layer having a specific Mg concentration (designed value) in each Experiment was grown according to the following steps.

(a) The relationship between the ratio [Mg/III-group ratio] of feeding amount of Mg source material (Cp₂Mg) to feeding amount of III-group source material (TMG, TMA) and Mg concentration in the crystal to be actually obtained, when growing a GaN-based semiconductor crystal layer having the composition desired to be grown by the MOVPE method is investigated in advance. The film thickness of the crystal layer to be grown therefor is set to about 300 nm, and the Mg concentration is measured by SIMS.

(b) From the above-mentioned relationship, the [Mg/III-group ratio] affording a predetermined design value of the Mg concentration is determined, and a GaN-based crystal layer is grown by the MOVPE method by feeding the Mg source material and the III-group source material at the [Mg/III-group ratio].

It was confirmed by SIMS that the Mg concentration of each layer was generally the design value. Particularly, when the vicinity of the surface of the crystal layer was measured by SIMS, the etching rate was decreased to increase the resolution in the depth direction.

The present invention is not limited to the Examples described above.

### INDUSTRIAL APPLICABILITY

From the practical viewpoint, a semiconductor light emitting element merely showing a high output power is not sufficient. Given the strong demand from the side of the apparatus or equipment in which the light emitting element is to be incorporated, lower electrical power consumption by a light emitting element is strongly requested. To meet the request, the operating voltage of a light emitting element needs to be reduced. Since the operating voltage of a light emitting element is directly related to a calorific value of the light emitting element, where a higher operating voltage causes a higher calorific value, the possibility of damage by heat increases, affecting the life of the light emitting element. Therefore, when the operating voltage of an element is high, a mounting structure preferentially releasing the heat is required, which in turn problematically produces various restrictions on the design. In particular, since a GaN-based semiconductor light emitting element generates a short wavelength light, the driving voltage becomes, in principle, inevitably high. In addition, sapphire, which is currently considered to be an optimal substrate for crystal growth, has extremely low thermal conductivity, and is difficult to function as a heat release medium. From the above situation, it is considered desirable to reduce, even by 0.1V, the operating voltage of a GaN-based semiconductor light emitting element, such as the forward voltage (Vf) of LED and the oscillation threshold voltage in LD.

According to the present invention, despite the fact that AlGaN is used as a material of the p-type contact layer, the operating voltage can be set lower than for a GaN-based semiconductor light emitting element having a p-type contact layer made of GaN heretofore considered optimal as a material of a p-type contact layer. When, for example, applied to LD, therefore, an effect can be afforded in that the threshold value of laser oscillation can be reduced. The present inventors assume that the decrease in the operating voltage of a GaN-based semiconductor light emitting element of the present invention is attributable to a decrease in the contact resistance between a p-type contact layer and a p-side electrode. The decrease in the contact resistance not only decreases the operating voltage of the element but also contributes to the suppression of the deterioration of the vicinity of the p-side electrode and improvement of the operation life and reliability of the element.

This application is based on a patent application No. 2004-175506 filed in Japan, the contents of which are incorporated in full herein by this reference.

1-9. (canceled)

10. A nitride semiconductor light emitting element comprising a laminate comprising a nitride semiconductor crystal layer, wherein the laminate comprises an n-type layer and a p-type layer, and the p-type layer comprises a p-type contact layer to be in contact with a p-side electrode,
the p-type contact layer comprises the first contact layer to be in contact with the p-side electrode on one surface side and the second contact layer to be in contact with the other surface of the first contact layer,
the first contact layer consists of Alₓ₁In_{y1}Ga_{z1}N wherein 0<x1≦0.2, y1=0, 0≦z1≦1, x1+y1+z1=1,
the second contact layer consists of Alₓ₂In_{y2}Ga_{z2}N wherein 0≦x2≦1, 0≦y2≦1, 0≦z2≦1, x2+y2+z2=1,
0≦x2<x1, and y1≦y2, and
the first contact layer has a thickness of 0.5 nm-2 nm.

11. The element of claim 10, wherein x2=y2=0.

12. The element of claim 10, wherein said p-type contact layer is doped with Mg, a p-type impurity, at a concentration of 1×10¹⁹-1×10²¹/cm³.

13. The element of claim 12, wherein said p-type layer comprises a high Mg concentration layer having a layer thickness of 6 nm-30 nm, which includes the first contact layer and which is doped with Mg at a concentration of not less than 5×10¹⁹/cm³, and the other part has an Mg concentration of less than 5×10¹⁹/cm³.

14. The element of claim 13, wherein said high Mg concentration layer has an Mg concentration of not more than 1×10²⁰/cm³.

15. The element of claim 13, comprising, between said n-type layer and said p-type layer, a light emitting layer including an InGaN crystal layer emitting a light of a wavelength of not more than 420 nm, wherein the p-side electrode is an opening electrode made of an opaque metal film.

16. The element of claim 15, wherein said opening electrode has an area ratio of the metal film:opening of 40:60-20:80.

17. The element of claim 15, wherein said p-side electrode has an insulating film formed thereon, which permits transmission of the light generated by said light emitting layer, and the insulating film has a reflecting film on the surface thereof to reflect the light.

18. A nitride semiconductor light emitting element comprising a laminate comprising a nitride semiconductor crystal layer, wherein the laminate comprises an n-type layer and a p-type layer, and the p-type layer comprises a p-type contact layer to be in contact with a p-side electrode,
the p-type contact layer comprises the first contact layer to be in contact with the p-side electrode on one surface side and the second contact layer to be in contact with the other surface of the first contact layer,
the first contact layer consists of Alₓ₁In_{y1}Ga_{z1}N wherein 0<x1≦1, 0≦y1≦1, 0≦z1≦1, x1+y1+z1=1,
the second contact layer consists of Alₓ₂In_{y2}Ga_{z2}N wherein 0≦x2≦1, 0≦y2≦1, 0≦z2≦1, x2+y2+z2=1,
0≦x2<x1, and 0<y1<y2,
the first contact layer has a thickness of 0.5 nm-2 nm, and
the p-side electrode is made of a semiconductor material comprising a metal oxide.

19. The element of claim 18, wherein 0<x1≦0.2 and y1=0.

20. The element of claim 18, wherein x2=y2=0.
